(19) United States
(12) Patent Application Publication
(10) Pub. No.: US 2010/0243999 A1
(43) Pub. Date: Sep. 30, 2010

(54) ORGANIC ELECTRONIC DEVICE, ORGANIC ELECTRONIC DEVICE MANUFACTURING METHOD, ORGANIC ELECTRONIC DEVICE MANUFACTURING APPARATUS, SUBSTRATE PROCESSING SYSTEM, PROTECTION FILM STRUCTURE AND STORAGE MEDIUM WITH CONTROL PROGRAM STORED THEREIN

(75) Inventor: Hiraku Ishikawa, Sendai City (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/675,351

(22) PCT Filed: Aug. 26, 2008
(86) PCT No.: PCT/JP2008/065166

§ 371 Date: Feb. 25, 2010

(30) Foreign Application Priority Data
Aug. 31, 2007 (JP) 2007-225144

(51) Int. Cl. H01L 51/52; H01L 51/56; B32B 43/00; C23C 16/513; C23C 16/511; B05C 11/00; B32B 9/04

(52) U.S. Cl. 257/40; 438/99; 156/349; 118/723 MW; 118/723 AN; 118/697; 428/688; 257/E51.018

(57) ABSTRACT

An organic element is protected by a protection film which has high sealing performance while relaxing a stress and does not change the characteristics of the organic element. In a substrate processing system Sys, a substrate processing apparatus 10, which includes a deposition apparatus PM1, a first microwave plasma processing apparatus PM3, and a second microwave plasma processing apparatus PM4, is arranged in a cluster structure, and an organic electronic device is manufactured by keeping a space where a substrate G moves from carry-in to carry-out in a desired depressurized state. An organic EL element is formed by the deposition apparatus PM1, butyne gas is plasmatized by microwave power by the first microwave plasma processing apparatus PM3, and an aCHx film 54 is formed adjacent to the organic EL element to cover the organic EL element. Then, silane gas and nitrogen gas are plasmatized by microwave power by the second microwave plasma processing apparatus PM4, and a SiNx film 55 is formed on the aCHx film 54.

### TECHNICAL FIELD

The present invention relates to an organic electronic device, an organic electronic device manufacturing method, an organic electronic device manufacturing apparatus, a substrate processing system, a protection film structure, and a storage medium with control program stored therein. More particularly, the present invention relates to the structure of a film for protecting an organic element, and a method of manufacturing an organic electronic device by using the film for protecting the organic element.

### BACKGROUND ART

Recently, an organic electroluminescence (EL) display that uses an organic EL element for emitting light using an organic compound has attracted attentions. Since organic EL elements are self-emissive, provide a fast response, and consume low power, they do not require a backlight and, for example, such organic EL elements are anticipated to be applied to display units of portable apparatuses.

An organic EL element is formed on a glass substrate and has a structure in which an organic layer is sandwiched between an anode and a cathode. The organic layer is sensitive to moisture or oxygen. When moisture or oxygen is mixed with the organic layer, the characteristics of the organic layer are changed, and thus non-emissive points (dark spots) are generated. This causes the durability of organic EL elements to be decreased. Accordingly, when an organic electronic device is manufactured, an organic element needs to be sealed to prevent external moisture or oxygen from penetrating into the organic electronic device.

Thus, conventionally, in order to protect the organic layer from external moisture or oxygen. A technique which uses a sealing can, such as a metal can, has been suggested (see a non-patent document 1). According to this conventional technique, the sealing can is attached onto an organic EL element, and a drying agent is also attached to the inside of the sealing can, so that the organic EL element is sealed and dried. Thus, moisture is prevented from being mixed into the organic EL element.

In consideration of making a thinner device, using a conventional technique of sealing an organic element with a dense thin film instead of the sealing can has been suggested (see Patent Document 2). This dense thin film needs to be not only moisture-repellent and oxidization-resistant but also needs to be formed at low temperature, provide a low stress, and sufficiently protect an organic element from a physical impact. In particular, in a high-temperature process, the organic element is damaged during the process. To prevent this damage, a silicon nitride (SiN) film capable of being formed at a low temperature of 100° C. or less by chemical vapor deposition (CVD) is considered important for the protective film.

Although the SiN film is dense and has a high sealing performance, the SiN film provides a high tensile stress. When a tensile stress is high, the tensile stress is applied in a direction in which the film is bent in a bowl shape. Thus, the film is taken off, or the vicinity of an interface between the organic element and the protective film is damaged.

Thus, a technique of sealing an organic EL element with a multi-layered protection film in which a low-density film and a high-density film are stacked has also been suggested (e.g., see Patent Document 3). According to this technique, the organic EL element is mainly sealed with the high-density film, and a stress is relaxed by the low-density film, so that the protection film is prevented from being cracked or detached.

[Non-patent document 1] Tatsuya YOSHIZAWA “Developing an Organic EL Film Display”, Textile Chemistry Magazine (Japan), Vol. 59, No. 12, pp. P_{—}407-P_{—}411 (2003)

[Patent document 2] Japanese Laid-open Patent Publication No. 2003-282237

[Patent document 3] Japanese Laid-open Patent Publication No. 2003-282242

### DISCLOSURE OF THE INVENTION

### Technical Problem

However, since an organic element is very delicate, is easily affected by the environment, and is hierarchically formed, a mechanical strength is weak particularly on an interface between layers. Thus, although a protection film is hierarchically formed of a film which makes a good seal and a film which relaxes stress well, the entire protection film does not keep a good balance between sealing performance and stress relaxing performance. Thus, a large force may be applied locally to an interface of one layer within an organic device, or in some cases, due to the composition of the protection film, the protection film may affect the organic element, so that the characteristics of the organic element may be changed.

To address this problem, the present invention provides a protection film for an organic electron device, which keeps high sealing performance while relaxing a stress and does not change the characteristics of an organic element.

### Technical Solution

According to an aspect of the present invention, there is provided an organic electronic device including an organic element formed on a target object; and a protection film that covers the organic element, wherein the protection film includes a stress relaxing layer that is formed to be adjacent to the organic element and cover the organic element, contains a carbon component and contains no nitrogen components; and a sealing layer that is formed on the stress relaxing layer and contains a nitrogen component.

In this structure, since the protection film has a hierarchical structure including the stress relaxing layer and the sealing layer, the stress relaxing layer is formed to be closely contacted to the organic element to cover the organic element, and the sealing layer is formed on the stress relaxing layer. Since the stress relaxing layer contains carbon, it has a smaller stress than the sealing layer. Therefore, the stress of the sealing layer may be relaxed by the stress relaxing layer, and thus an excessive stress may be prevented from being applied to the organic element. Consequently, detachment of the stress relaxing layer from the organic element or destruction of the vicinity of the interface of the organic element by the stress may be prevented.

In addition, since the stress relaxing layer contains no nitrogen component, the organic element, which is an underlayer of the stress relaxing layer, is not nitrified even when it is closely attached to the stress relaxing layer. Thus, for example, the risk that an electrode portion of the organic element is nitrified to be changed from a conductor to an insulation layer (or a dielectric layer), so that electricity is difficult to flow, or nitrogen is directly mixed with the organic element does not exist. Accordingly, the risk of degrading the characteristics essentially required by the organic element, such as luminous intensity or mobility, is removed. Consequently, a durable and practical organic EL element device capable of protecting the organic element from moisture or oxidization while keeping the characteristics of the organic element in a good state and reducing a stress applied to the organic element by using a protection film may be manufactured.

The stress relaxing layer may be an amorphous hydrocarbon (aCHx) film (hereinafter, also referred to as an aCHx film). The aCHx film is moisture-repellent because it is somewhat dense. In addition, since the aCHx film includes carbon, it has a smaller stress than a nitride film, and is suitable to serve as the stress relaxing layer by being interposed between the organic element and the sealing layer. Moreover, since the aCHx film includes no nitrogen (N), there is no risk of damaging the organic element by nitrifying the organic element which is the underlayer. Also, the aCHx film has a high mechanical strength and high light-transmittance. In particular, if the organic element is an organic electroluminescence (EL) element, it is important to use, as the stress relaxing layer, the aCHx film having high light-transmittance instead of a CN film that absorbs light. Moreover, since the aCHx film is hydrophobic, it does not transmit moisture and does not leave oxygen due to a reduction reaction of hydrogen with oxygen around the hydrogen. In other words, the aCHx film may be considered as one of the best protection films to be formed by being closely attached to organic element because the aCHx film is good in terms of moisture repellence, oxidation resistance and high light-transmittance, and relaxes a stress to some extent while keeping the characteristics of the organic element in a good state.

The sealing layer may be a silicon nitride film (hereinafter, also referred to as a SiN film). The SiN film is highly dense and has a high sealing performance. For example, a SiO₂ film transmits water, and the SiN film blocks water, thus, the SiN film is highly moisture-repellent. However, since the SiN film is highly dense, it has a higher stress than the SiO₂ film, and thus when the SiN film is closely attached to the organic element, a large stress is applied to the organic element, thereby causing the organic element to be deformed or detached. Also, since the SiN film is formed of nitride, there is a possibility of degrading the characteristics of the organic element by nitrifying the organic element. Therefore, in the present invention, the SiN film is formed on the outermost side in order to securely block moisture or oxygen from an external source. In addition, the aCHx film is interposed between the SiN film and the organic element to prevent the vicinity of the interface of the organic element from being damaged due to direct application of a stress of the SiN film to the organic element or to prevent the characteristics of the organic element from being changed due to nitrification of the organic element by using nitrogen contained in the SiN film.

A close-contact layer formed of a coupling agent may be interposed between the organic element and an exposed portion of the target object and the stress relaxing layer. Accordingly, the close-contact layer formed on the organic element and the exposed portion of the target object may serve as an adhesive so as to reinforce the close-contact property between the organic element and the stress relaxing layer. Thus, the stress relaxing layer may be prevented from being detached from the organic element.

The silicon nitride film may include a first silicon nitride film and a second silicon nitride film obtained by further nitrifying the first silicon nitride film. When the silicon nitride film is further nitrified, it turns into a denser film, and thus has improved sealing performance but also has high stress. Thus, when the second silicon nitride film having a higher stress than the first silicon nitride film is thickened, the silicon nitride film is cracked or detached due to the very large stress. To prevent this problem, a film thickness ratio of the second silicon nitride film to the first silicon nitride film is suitable to be about ½ to about ⅓.

As described above, the SiN film needs to be somewhat thin in order to maintain a balance between the oxygen resistance or moisture repellency of the protection film and a stress existing in the protection film. For example, a sum of the thicknesses of the first SiN film and the second SiN film may be less than or equal to 1000 Å.

The second silicon nitride film may be interposed between first silicon nitride films. Alternatively, the first silicon nitride film and the second silicon nitride film may be alternately stacked to have one layer each or two layers each. In this case, the one having two layers each stacked alternatively has a greater overall film thickness than the one having one layer each stacked alternatively, but the stress of the one having two layers each is not likely to be high.

The aCHx film may be somewhat thick, for example, in the range of 500 to 3000 Å. By having such a somewhat high thickness, the aCHx film may relax the stress generated in the SiN film, thereby reducing a stress on the organic element. Also, by having such a somewhat high thickness, the aCHx film may prevent nitrogen included in the SiN film from reaching the organic element. In more detail, oxygen molecules or water molecules may be diffused by a distance determined according to a diffusion coefficient of each. Accordingly, if a period of time required for the oxygen molecules or the water molecules to reach the organic element is longer than a period of time required for the oxygen molecules or the water molecules to be destroyed while being diffused, the oxygen molecules or the water molecules do not affect the organic element. Thus, the organic element is marketable. Therefore, in relation to the diffusion coefficient, if the aCHx film has a thickness of 500 to 3000 Å, even when the oxygen molecules or the water molecules passes through the SiN film and enters the organic element, the probability that the oxygen molecules or the water molecules affect the organic element in a bad way is considered very low.

According to another aspect of the present invention, there is provided a method of manufacturing an organic electronic device, the method including forming an organic element on a target object; and stacking a stress relaxing layer to be adjacent to the organic element and cover the organic element, to serve as one layer included in a protection film that protects the organic element, wherein the stress relaxing layer contains a carbon component and contains no nitrogen components; and stacking a sealing layer on the stress relaxing layer to serve as another layer included in the protection film, wherein the sealing layer contains a nitrogen component.

After a close-contact layer is formed of a coupling agent on the organic element and an exposed portion of the target object, the stress relaxing layer may be stacked on the close-contact layer.

An amorphous hydrocarbon film may be formed as the stress relaxing layer.

The amorphous hydrocarbon film may be formed in a process condition where an internal pressure of a processing chamber of a microwave plasma processing apparatus is 20 mTorr or less, microwave power supplied into the processing chamber is 5 kw/cm² or greater, and a temperature around the target object (for example, a surface temperature of the target object) loaded within the processing chamber is 100° C. or less.

A first silicon nitride film may be formed as the sealing layer by using plasma generated by exciting a gas comprising a silane gas and a nitrogen gas by microwave power.

The first silicon nitride film may be formed in a process condition where an internal pressure of a processing chamber of a microwave plasma processing apparatus is 10 mTorr or less, microwave power supplied into the processing chamber is 5 kw/cm² or greater, and a temperature around the target object loaded within the processing chamber is 100° C. or less. The reason is that the organic element (for example, an organic EL element) is weak to the high temperature and is damaged if a maximum temperature during a process is greater than 100° C. Thus, during the formation of the first silicon nitride film, the temperature around the target object may be set to be 70° C. or less.

After the first silicon nitride film is formed, by pausing a supply of the silane gas and nitrifying the first silicon film by a nitrogen gas so as to reform the first silicon nitride film, the second silicon nitride film that is denser than the first silicon nitride film may be formed.

The formation of the first silicon nitride film and the formation of the second silicon nitride film by reformation of the first silicon nitride film may be consecutively performed by repeating the pause of the supply of the silane gas and resumption of the supply of the silane gas.

In this consecutive process, it is preferable that a film thickness ratio of the second silicon nitride film to the first silicon nitride film is controlled to be ½ to ⅓ by controlling the timings of the pause of the supply of the silane gas and the resumption of the supply of the silane gas. As described above, if the second silicon nitride film is greater than the above-set thickness, the SiN film may be cracked or detached.

Before the close-contact layer formed of the coupling agent is formed on the organic element and the exposed portion of the target object, the organic element and the exposed portion of the target object may be cleaned using plasma generated by exciting an inert gas by microwave power. Accordingly, a material attached to the organic element (for example, an organic material) may be removed to increase close-contact between the organic element and the aCHx film.

The cleaning may be performed in a process condition where an internal pressure of a processing chamber of a microwave plasma processing apparatus is 100 to 800 mTorr or less, microwave power supplied into the processing chamber is 4 to 6 kw/cm², and a temperature around the target object is 100° C. or less.

The amorphous hydrocarbon film and the silicon nitride film may be formed using a plasma processing apparatus including a radial line slot antenna (RLSA). Accordingly, an electron temperature is lower in the RLSA type microwave plasma processing apparatus than in a parallel plate plasma processing apparatus. Thus, dissociation of gas is controllable, and thus a high quality film may be formed.

The amorphous hydrocarbon film may be formed in the microwave plasma processing apparatus where the cleaning has been performed.

A bias voltage may be applied during at least one selected from the group consisting of a period of time when the stress relaxing layer is stacked and a period of time when the sealing layer is stacked.

According to another aspect of the present invention, there is provided an apparatus for manufacturing an organic electronic device, wherein the apparatus forms an organic element on a target object; stacks a stress relaxing layer to be adjacent to the organic element and cover the organic element, to serve as one layer included in a protection film that protects the organic element, wherein the stress relaxing layer contains a carbon component and contains no nitrogen components; and stacks a sealing layer on the stress relaxing layer to serve as another layer included in the protection film, wherein the sealing layer contains a nitrogen component.

According to another aspect of the present invention, there is provided a substrate processing system in which a substrate processing apparatus comprising a deposition apparatus, a first microwave plasma processing apparatus, and a second microwave plasma processing apparatus is arranged in a cluster structure, and an organic electronic device is manufactured while maintaining a space where a target object moves from carry-in to carry-out in a desired depressurized state, wherein the substrate processing system forms an organic element within a processing chamber of the deposition apparatus; generates plasma by exciting a gas comprising a butyne gas by microwave power and forms an amorphous hydrocarbon film to be adjacent to the organic element and cover the organic element, by using the plasma, within a processing chamber of the first microwave plasma processing apparatus; and generates plasma by exciting a gas comprising a silane gas and a nitrogen gas by microwave power and forms a first silicon nitride film on the amorphous hydrocarbon film, by using the plasma, within a processing chamber of the second microwave plasma processing apparatus.

The first microwave plasma processing apparatus and the second microwave plasma processing apparatus may be plasma processing apparatuses each including an RLSA.

After the organic element and an exposed portion of the target object are cleaned in the processing chamber of the first microwave plasma processing apparatus, an amorphous hydrocarbon film may be consecutively formed within the same processing chamber.

The substrate processing system may include a processing chamber in which a close-contact layer formed of a coupling agent is formed on the organic element and the exposed portion of the target object. After the organic element and the exposed portion of the target object are cleaned, the close-contact layer may be formed in the processing chamber, and the amorphous hydrocarbon film may be stacked in the first microwave plasma processing apparatus.

The organic element may be an organic EL element in which a plurality of organic layers are consecutively formed in the processing chamber of the deposition apparatus.

According to another aspect of the present invention, there is provided a protection film structure for protecting an organic element formed on a target object, the protection film structure including a stress relaxing layer stacked adjacent to the organic element to cover the organic element, to serve as one layer included in the protection film for pretecting the organic element, wherein the stress relaxing layer contains a carbon component and contains no nitrogen components; and a sealing layer stacked on the stress relaxing layer to serve as another layer included in the protection film for protecting the organic element, wherein the sealing layer contains a nitrogen component.

In the protection film structure, a close-contact layer formed of a coupling agent may be interposed between the organic element and an exposed portion of the target object and the stress relaxing layer.

According to another aspect of the present invention, there is provided a computer-readable recording medium having recorded thereon a control program that operates on a computer, wherein the computer controls a substrate processing system to manufacture an organic electronic device according to the method of manufacturing the organic electronic device.

### ADVANTAGEOUS EFFECTS

As described above, the present invention provides an organic electronic device to covered with a protection film which has high sealing performance while relaxing a stress and does not change the characteristics of an organic element, and a method of manufacturing the organic electronic device.

### BRIEF DESCRIPTION OF THE DRAWINGS

FIG. 1 shows a method of manufacturing a device, according to Embodiment I of the present invention;

FIG. 2 is a diagram of a substrate processing system according to Embodiments I and II of the present invention;

FIG. 3 is a vertical cross-sectional view of a deposition apparatus according to Embodiments I and II of the present invention;

FIG. 4 is a vertical cross-sectional view of a silylation apparatus according to Embodiments I and II of the present invention;

FIG. 5 is a vertical cross-sectional view of a Radial Line Slot Antenna (RLSA)-type microwave plasma processing apparatus according to Embodiments I and II of the present invention;

FIG. 6 shows a timing chart of each condition and a film-formation state at each timing, in a process of manufacturing the sealing layer according to Embodiment II of the present invention;

FIG. 7A shows another film-formation state of the sealing layer;

FIG. 7B shows another film-formation state of the sealing layer;

FIG. 8 is a timing chart of application of a bias voltage in the process of manufacturing the sealing layer;

FIG. 9 is another timing chart of application of a bias voltage in the process of manufacturing the sealing layer; and

FIG. 10 is another timing chart of application of a bias voltage in the process of manufacturing the sealing layer.

### EXPLANATION OF REFERENCE NUMERALS DESIGNATING THE MAJOR ELEMENTS OF THE DRAWINGS

10: substrate processing apparatus
20: controller
50: ITO
51: organic layer
52: metal electrode
53: close-contact layer
54: aCHx film
55: SiNx film
55a: SiNyHx film
55b: Si₃N₄ film
G: glass substrate
Sys: substrate processing system

### MODE FOR INVENTION

Hereinafter, Embodiment I of the present invention will be described with reference to the attached drawings. Like reference numerals in the drawings and the below description denote like elements, and a detailed description thereof will be omitted. In the present specification, 1 mTorr is (10⁻³×101325/760)Pa, 1 sccm is (10⁻⁶/60)m³/sec, and 1 Å is 10⁻¹⁰ m.

### Embodiment I

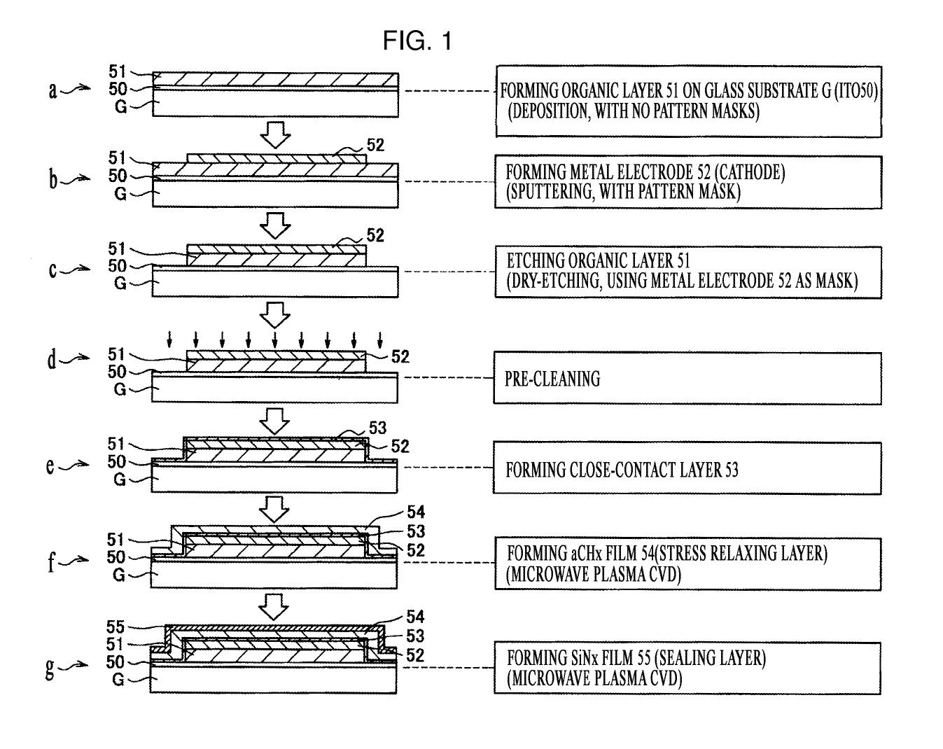

A method of manufacturing an organic electronic device, according to Embodiment I of the present invention, will now be described with reference to FIG. 1. The explanation of the present embodiment includes a process of sealing an organic electroluminescence (EL) element for an organic EL element device.

(Method of Manufacturing Organic EL Element Device)

As shown in a cross section a of FIG. 1, a glass substrate G on which an indium tin oxide (ITO) 50 is formed as an anode layer is prepared, and the surface thereof is cleaned. Thereafter, an organic layer 51 is formed on the ITO (anode) 50 by deposition.

Thereafter, as shown in a cross section b of FIG. 1, target atoms (for example, Ag) are deposited on the organic layer 51 via a pattern mask by sputtering, thereby forming a metal electrode (cathode) 52. Hereinafter, what is referred to as an organic EL element includes the organic layer 51 and the metal electrode 52 is.

Then, as shown in a cross section c of FIG. 1, the organic layer 51 is etched using the metal electrode 52 as a mask. Then, as shown in a cross section d of FIG. 1, the organic EL element and an exposed portion of the glass substrate G (that is, the ITO 50) are cleaned to remove a material (for example, an organic material) adsorbed to the organic EL element. This process is called pre-cleaning.

Next, as shown in a cross section e of FIG. 1, a close-contact layer 53, which is very thin, is formed using a coupling agent by silylation. Examples of the coupling agent may include HMDS(Hexamethyldisilan), DMSDMA(Dimethylsilyldimethylamine), TMSDMA(Trimethylsilyldimethylamine), TMDS(1,1,3,3-Tetramethyldisilazane), TMSPyrole(1-Trimethylsilylpyrole), BSTFA(N,O-Bis(trimethylsilyl)trifluoroacetamide), and BDMADMS(Bis(dimethylamino)dimethylsilane). These coupling agents have the following chemical structures:

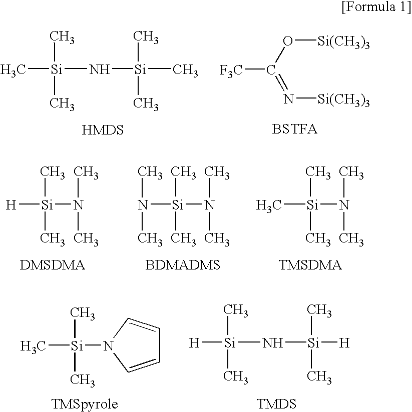

In the close-contact layer 53, NH component included in the coupling agent (HMDS) of the above-shown composition has high reactivity, thus a combination of NH and Si is broken by certain applied energy, and the separated Si is chemically combined with the organic EL element, which is located below, so that the close-contact layer 53 strongly close-contacted to the organic EL element. Since CHx included in an amorphous hydrocarbon (aCHx) film 54 deposited on the close-contact layer 53 has the same component as CH₃ included in the close-contact layer 53, close-contact property (continuity) between the close-contact layer 53 and the aCHx film 54 formed thereon is high.

As described above, the close-contact layer 53 is formed between the organic EL element and the aCHx film 54, and the aCHx film 54 is grown on the close-contact layer 53, so that the close-contact property between the organic EL element and the aCHx film 54 is increased due to the adhesion effect of the Si included in the close-contact layer 53 with the organic EL element. Accordingly, the organic EL element can be protected. Since the close-contact layer 53 has a thickness less than 3 nm, even if the close-contact layer 53 contains nitrogen, the close-contact layer 53 may not change the characteristics of the organic EL element.

Then, as shown in a cross section f of FIG. 1, the aCHx film 54 is formed. The aCHx film 54 is formed by microwave plasma chemical vapor deposition (CVD). In more detail, plasma is formed by exciting a gas including butyne gas (C₄H₆) by using microwave power, and an aCHx film 54 of high quality is formed at a low temperature less than or equal to 100° C. by using the plasma. Since the organic EL element is damaged at a high temperature greater than 100° C., the aCHx film 54 needs to be formed in a low temperature process at the low temperature less than or equal to 100° C.

Similarly, a SiNx film (silicon nitride film) 55 shown in a cross section g of FIG. 1 is also formed in the low temperature process at the low temperature less than or equal to 100° C. by microwave plasma CVD.

In the present embodiment, since a protection film has a hierarchical structure including the aCHx film 54 and the SiNx film 55 as described above, the aCHx film 54 is closely contacted to the organic EL element (the organic layer 51 and the metal electrode 52) to cover the organic EL element, and the SiNx film 55 seals the entire resultant structure at outer side. Since the aCHx film 54 contains carbon, it has a smaller stress than the SiNx film 55. Therefore, the stress of the SiNx film 55 may be relaxed by the aCHx film 54, and thus an excessive stress may be prevented from being applied to the organic EL element. Consequently, detachment of the aCHx film 54 from the organic EL element or destruction of the vicinity of the interface of the organic EL element may be prevented.

In addition, since the aCHx film 54 contains no nitrogen, the organic EL element has no risk of being nitrified although it is closely contacted to the aCHx film 54. Thus, for example, the metal electrode 52 of the organic EL element is nitrified to be changed from a conductor to an insulation layer (or a dielectric layer), so that it is difficult for electricity to flow, or nitrogen is directly mixed with the organic layer 51. Accordingly, the risk of degrading the characteristics essentially required by the organic EL element, such as luminous intensity or mobility, is removed. Consequently, an organic EL element may be protected by a protection film that is moisture-repellent and oxidization-resistant while relaxing a stress, and does not change the characteristics of the organic EL element, so that a durable and practical organic EL element device may be manufactured.

In particular, in the present embodiment, the aCHx film 54 is exemplified as a stress relaxing layer for the following reasons. That is to say, the aCHx film 54 is moisture-repellent because it is somewhat dense. In addition, the aCHx film 54 has a smaller stress than a nitride film since it includes carbon, and is interposed between the organic EL element and the SiNx film 55 so as to relax the stress. Moreover, since the aCHx film 54 includes no nitrogen (N), there is no risk of damaging the organic EL element by nitrifying the organic EL element, which is an underlayer of the aCHx film 54. Also, the aCHx film 54 has a high mechanical strength and high light-transmittance. Since a CN film absorbs light, it has an important meaning that an organic EL element uses, as a stress relaxing layer, the aCHx film 54 having high light-transmittance instead of the CN film. Since the aCHx film 54 is hydrophobic, it does not transmit moisture and does not leave oxygen due to a reduction reaction of hydrogen with oxygen around the hydrogen. In other words, the aCHx film 54 may be considered as one of the best materials that are closely contacted to organic elements to protect them, because the aCHx film 54 is good in terms of moisture repellence and oxidation resistance.

In the present embodiment, the SiNx film 55 is exemplified as a sealing layer for the following reasons. That is to say, the SiNx film 55 is highly dense and has a high sealing performance. For example, while a SiO₂ film transmits water, the SiNx film 55 blocks water. Thus, the SiNx film 55 is highly moisture-repellent. However, since the to SiNx film 55 is highly dense, it has a higher stress than the SiO₂ film, and thus when the SiNx film 55 is closely contacted to the organic EL element, a large stress is applied to the organic EL element, thereby it can cause the organic EL element to be deformed or detached. Also, since the SiNx film 55 is formed of nitride, there is a possibility of degrading the characteristics of the organic EL element by nitrifying the organic EL element.

Therefore, in the present embodiment, the SiNx film 55 is formed on the outermost side in order to securely block moisture or oxygen from an external source to prevent the organic EL element from being degraded by moisture or oxygen. In addition, the aCHx film 54 is formed to have a certain thickness between the SiNx film 55 and the organic EL element to prevent the vicinity of the interface of the organic EL element from being damaged due to direct application of a stress of the SiNx film 55 to the organic EL element or to prevent the characteristics of the organic EL element from being degraded due to nitrification of the organic EL element. In particular, in the present embodiment, the close-contact between the organic EL element and the aCHx film 54 is reinforced by the close-contact layer 53, and thus the detachment of the aCHx film 54 from the organic EL element may be more strongly prevented.

### (Substrate Processing System)

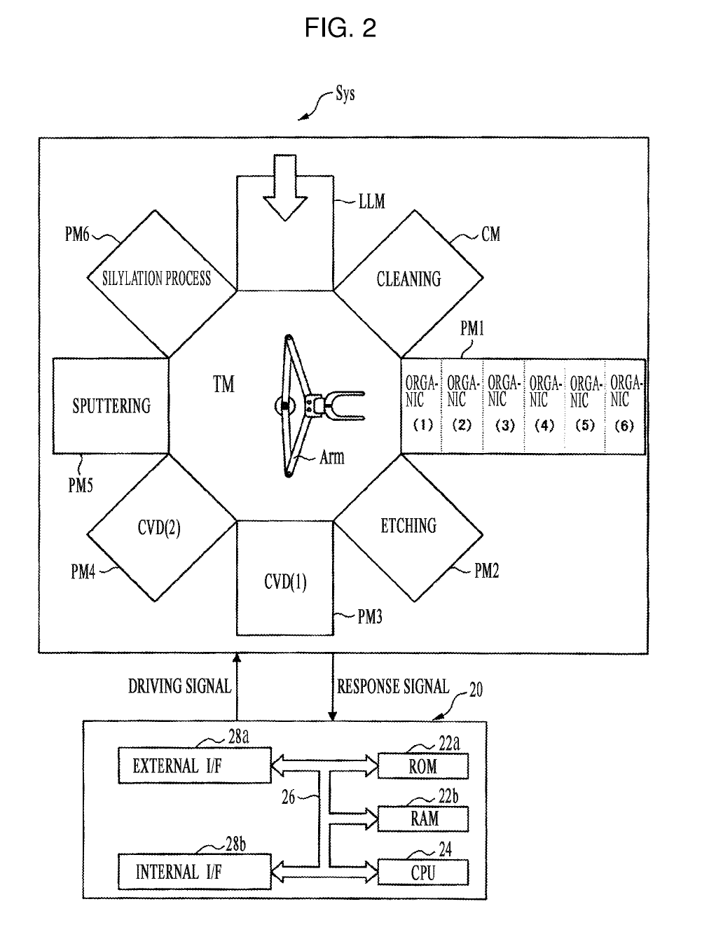

A substrate processing system for performing the series of processes shown in FIG. 1 will now be described with reference to FIG. 2. The substrate processing system Sys according to the present embodiment includes a cluster type substrate processing apparatus 10 including a plurality of processing apparatuses, and a controller 20 for controlling the substrate processing apparatus 10.

### (Cluster Type Substrate Processing Apparatus 10)

The substrate processing apparatus 10 includes a load-lock module LLM, a transfer module TM, a cleaning module CM, and six process modules PM1 through PM6.

The load-lock module LLM is a vacuum transfer module whose inside is maintained in a predetermined depressurized state in order to transfer the glass substrate G received from the air field to the transfer module TM that is in a depressurized state. The transfer module TM includes a multi-joint transfer arm Arm, which can be bent/stretched and rotated, installed therein. The glass substrate G is first transferred from the load-lock module LLM to the cleaning module CM by using the transfer arm Arm. After the surface of the ITO of the glass substrate G is cleaned, the glass substrate G is transferred to the process module PM1, and additionally to the other process modules PM2 through PM6. In the cleaning module CM, a contaminant (mainly, an organic material) attached to the surface of the ITO (anode layer) formed on the glass substrate G is removed.

First, in the process module PM1 from among the six process modules PM1 through PM6, 6 organic layers 51 are consecutively stacked on the surface of the ITO of the glass substrate G by deposition. Then, the glass substrate G is transferred to the process module PM5, in which the metal electrode 52 is formed by sputtering.

Next, the glass substrate G is transferred to the process module PM2, in which a part of the organic layer 51 is etched out. Thereafter, the glass substrate G is transferred to the cleaning module CM or the process module PM3, in which an organic material attached to an exposed part of the metal electrode 52 or the organic layer 51 during a process is removed. Then, the glass substrate G is transferred to the process module PM6, in which the close-contact layer 53 is formed by depositing a silane coupling agent such as HMDS on the organic EL element.

Next, in the process module PM3, the aCHx film 54 is formed on the glass substrate G by microwave plasma CVD. In the process module PM4, the SiNx film 55 is formed on the glass substrate G by microwave plasma CVD.

### (Controller 20)

The controller 20 is a computer for controlling the entire substrate processing system Sys. In more detail, the controller 20 controls transfer of the glass substrate G in the substrate processing system Sys and actual processes performed in the substrate processing apparatus 10. The controller 20 includes a read-only memory (ROM) 22a, a random access memory (RAM) 22b,a central processing unit (CPU) 24, a bus 26, an external interface (external I/F) 28a, and an internal interface (internal I/F) 28b.

The ROM 22a stores basic programs executed in the controller 20, programs operating during a disorder, a recipe indicating the sequence of processes of process modules, or else. The RAM 22b accumulates data representing a process condition of each process module, or a control program for executing processes. The ROM 22a and the RAM 22b are just examples of a storage medium. An Electrically Erasable Programmable Read-Only Memory (EEPROM), an optical disc, a magneto-optical disc, and the like may be used as the storage medium.

The CPU 24 controls a process for manufacturing an organic electronic device on the glass substrate G, by executing a control program according to various recipes. The bus 26 is a path along which devices transmit and receive data to and from each other. The internal I/F 28a receives the data and outputs necessary data to a monitor (not shown), a speaker (not shown), or the like. The external interface 28b transmits and receives data to and from the substrate processing apparatus 10 via a network.

For example, when a driving signal is transmitted from the controller 20, the substrate processing apparatus 10 transfers the glass substrate G indicated by the driving signal and drives a process module indicated by the driving signal, to control a necessary process and inform the controller 20 of a result of the control, that is, of a response signal. In this way, the controller 20 (computer) executes a control program stored in the ROM 22a or the RAM 22b, thereby controlling the substrate processing system Sys to perform the manufacturing process the organic EL element (device) shown in FIG. 1.

Internal structure of each of the process modules and specific processes performed in each of the process modules will now be described in detail. The process modules PM2 and PM5 that perform etching and sputtering, respectively, may be general apparatuses, so internal structures thereof will not be described herein.

(PM1: Deposition Performed to Form the Organic Layer 51)

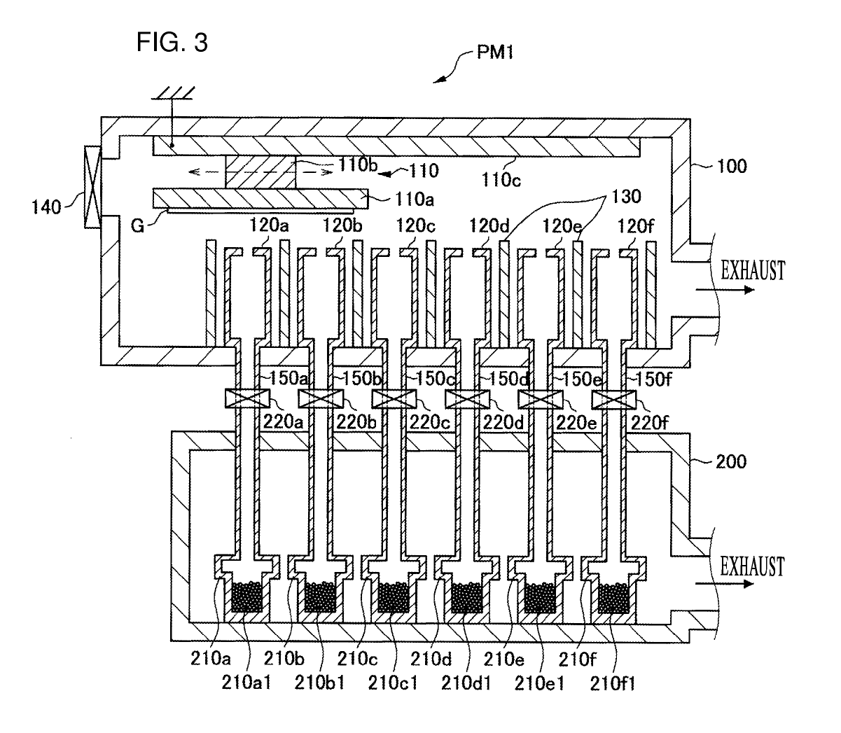

FIG. 3 is a vertical cross-sectional view of the process module PM1 (hereinafter, referred to as a deposition apparatus PM1). Referring to FIG. 3, the Deposition apparatus PM1 includes a first processing container 100 and a second processing container 200, and consecutively stacks 6 organic layers in the first processing container 100.

The first processing container 100 has a rectangular parallelepiped shape, and includes a sliding mechanism 110, six extraction mechanisms 120a through 120f, and seven barrier walls 130. A gate valve 140, through which it is possible to carry the glass substrate G into and out of the first processing container 100 while sealing the inner space of the first processing container 100 by opening or closing, is installed on a sidewall of the first processing container 100.

The sliding mechanism 110 includes a stage 110a, a holder 110b, and a sliding apparatus 110c. The stage 110a is held by the holder 110b, and the glass substrate G brought in through the gate valve 140 is electrostatically adsorbed onto the stage 110a by a high voltage received from a high voltage source (not shown). The sliding apparatus 110c is installed on the ceiling of the first processing container 100 and is also grounded, and thus slides the glass substrate G together with the stage 110a and the holder 110b in a length direction of the first processing container 100. Thus, the glass substrate G is moved horizontally in a space slightly above each of the extraction mechanisms 120.

The six extraction mechanisms 120a through 120f have identical shapes and identical structures and are arranged in parallel to each other at regular intervals. The extraction mechanisms 120a through 120f are hollowed to have a rectangular inside space so that organic molecules are extracted from openings formed in the upper portions of the extraction mechanisms 120a through 120f. The bottom of each of the extraction mechanisms 120 is connected to each of connection pipes 150a through 150f that penetrate a bottom surface of the first processing container 100.

The barrier walls 130 are respectively formed between adjacent extraction mechanisms 120. The barrier walls 130 separates the extraction mechanisms 120 from one another to thereby prevent organic molecules respectively extracted from each of the openings of the extraction mechanisms 120 from being mixed with one another.

The second processing container 200 includes six deposition sources 210a through 210f which have identical shapes and identical structures. The deposition sources 210a through 210f include reception units 210a1 through 210f1 to receive an organic material respectively. The reception units 210a1 through 210f1 are heated to a high temperature of about 200 to about 500° C. in order to vaporize the organic material. The vaporization in this context denotes not only a phenomenon in which liquid changes to vapor but also a phenomenon (that is, sublimation) in which solid is directly changed to vapor without passing through liquid state.

Upper portions of the deposition sources 210a through 210f are connected to the connection pipes 150a through 150f, respectively. The organic molecules vaporized in each of the deposition sources 210 does not stick to the connection pipes 150a through 150f, by maintaining the connection pipes 150a through 150f at a high temperature, and are emitted from the openings of the extraction mechanisms 120 to the inner space of the first processing container 100 via each of the connection pipes 150. The first and second processing containers 100 and 200 are depressurized to a desired vacuum degree by an exhaust mechanism (not shown) so that the inner spaces of the first and second processing containers 100 and 200 are maintained to a predetermined vacuum degree. Valves 220a through 220f are attached to the connection pipes 150, respectively, in the air and thus control connection and disconnection of the inner spaces of the deposition sources 210 to and from the inner space of the first processing container 100.

The glass substrate G already cleaned in the cleaning module CM is carried into the process module PM1 via the gate valve 140 having above-described structure and is moved sequentially over the openings of the extraction mechanisms in a direction from the extraction mechanism 120a toward the extraction mechanism 120f at a predetermined speed under the control of the controller 20. While the glass substrate G is moving, organic molecules sequentially extracted from the openings of the extraction mechanisms are deposited on the glass substrate G. Therefore, 6 organic layers including a hole transport layer, an organic emissive layer, and an electron transport layer are stacked on the glass substrate G. However, the organic layer 51 shown in the cross section a of FIG. 1 may not be a 6-story layer.

(PM4: Sputtering Performed to Form the Metal Electrode 52)

Thereafter, the glass substrate G is transferred to the process module PM5. The process module PM5 generates plasma by exciting gas supplied into a processing container under the control of the controller 20, makes ions included in the plasma collide with a target (that is, sputtering), and deposits target atoms (Ag) coming out of the target on the organic layer 51, thereby forming the metal electrode (cathode) 52 shown in the cross section b of FIG. 1.

(PM2: Etching Performed to Form the Organic Layer 51)

Then, the glass substrate G is transferred to the process module PM2. The process module PM2 dry-etches the organic layer 51 using plasma generated by exciting an etching gas under the control of the controller 20, by using the metal electrode 52 as a mask. Thus, the organic layer 51 as shown in the cross section c of FIG. 1 is formed.

(PM3: Pre-Cleaning)

Next, the glass substrate G is transferred to the cleaning module CM or the process module PM3 under the control of the controller 20. The cleaning module CM or the process module PM3 removes an organic material attached to the interface of the organic layer 51, by using plasma generated by exciting an argon gas.

During pre-cleaning, when the internal pressure of a processing chamber of the process module PM3 (hereinafter, referred to as a microwave plasma processing apparatus PM3) is less than or equal to 100 to 800 mTorr, and a temperature around the glass substrate G (for example, a temperature of the surface of the glass substrate G) is less than or equal to 100° C., microwaves with power of 4 to 6 kw/cm² are introduced for about 15 to 60 seconds while a predetermined amount of argon gas (inert gas) is being supplied. Thus, plasma is generated by exciting the argon gas, and the organic material attached to the interface of the organic layer 51 is removed using the plasma. Therefore, close-contact between the interface of the organic layer 51 and the protection film may improve. In addition, a mixture gas obtained by mixing the argon gas and hydrogen that corresponds to 10% of the argon gas may be supplied.

(PM6: Formation of the Close-Contact Layer 53)

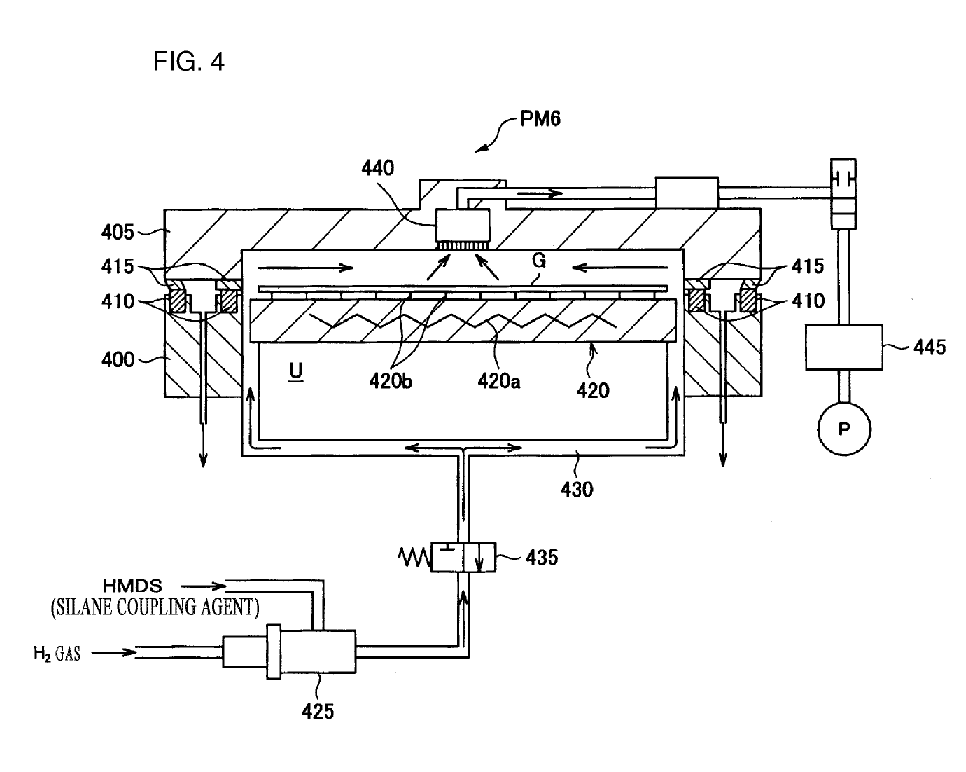

Then, the glass substrate G is transferred to the process module PM6 (hereinafter, referred to as a silylation apparatus PM6) under the control of the controller 20. The silylation apparatus PM6 performs silylation. FIG. 4 is a vertical cross-sectional view of the silylation apparatus PM6 that performs silylation.

The silylation apparatus PM6 includes a container 400 and a lid 405. First shield rings 410 are formed on inner and outer circumferences, respectively, of an upper portion of the container 400. Second shield rings 415 are formed on inner and outer circumferences, respectively, of a lower portion of the lid 405. When the lid 405 covers the upper portion of the container 400, the first shield rings 410 and the second shield rings 415 closely contact to each other at the inner and outer circumferences, and a space between the first shield rings 410 and the second shield rings 415 is depressurized, thereby an air-tightly maintained processing chamber U is defined.

A hot plate 420 is formed in the container 400. A heater 420a is buried in the hot plate 420 and controls the internal temperature of the processing chamber U to be in the range of a room temperature to 200° C. On the upper surface of the hot plate 420, pins 420b for holding the glass substrate G are formed, to be able to be elevated/lowered to facilitate transfer of the glass substrate G and prevent the back of the glass substrate G from being contaminated.

A silane coupling agent such as HMDS is vaporized by a vaporizer 425 to turn into vapor molecules. The vapor molecules pass through a gas flow path 430 by using N₂ gas as a carrier gas, and are supplied from the lateral sides of the hot plate 410 to an upper inner space of the processing chamber U. The supply of the silane coupling agent to the processing chamber U is controlled by opening or closing of an electronic valve 435. An exhaust hole 440 is installed at or near the center of the lid 405, so that the silane coupling agent and the N₂ gas supplied into the processing chamber U are exhausted using a pressure control device 445 and a vacuum pump P. Alternatively, the silylation apparatus PM6 may be turned upside down so that the silane coupling agent is supplied from the lateral sides of the hot plate 420 to a lower inner space of the processing chamber U by using the N₂ gas as the carrier gas and exhausted through an exhaust hole formed in the bottom surface of the silylation apparatus PM6 by using the pressure control device 445 and the vacuum pump P.

In the silylation apparatus PM6 having this structure, under the control of the controller 20, the hot plate 420 is controlled to have a predetermined temperature in the range of 50 to 95° C., the vaporizer 425 is controlled to have a predetermined temperature in the range of a room temperature to 50° C., and the internal pressure of the processing chamber U is vacuum sucked by the vacuum pump P so as to be 0.5 to 5 Torr. In this condition, the glass substrate G is loaded on the pins 420b of the hot plate 420, and silylation is performed on a just-cleaned organic EL element for 30 to 180 seconds while the silane coupling agent is being supplied at a flow rate controlled to be, for example, 0.1 to 1.0 (g/min) and the N₂ gas is being supplied at a flow rate controlled to be, for example, 1 to 10 (l/min). Accordingly, in-situ, the close-contact layer 53, which is mono-layered, due to the coupling agent is formed on the surface of the organic EL element. Moreover, after silylation, a gas remaining in the processing chamber (for example, NH separated from HMDS as the silane coupling agent) is exhausted by the vacuum pump P. The close-contact layer 53 shown in the cross section e of FIG. 1 reinforces the close-contact of the organic EL element and an exposed portion of the glass substrate G to the aCHx film 54, which is formed subsequently, due to the above-described operation.

(PM3: Formation of the aCHx Film 54)

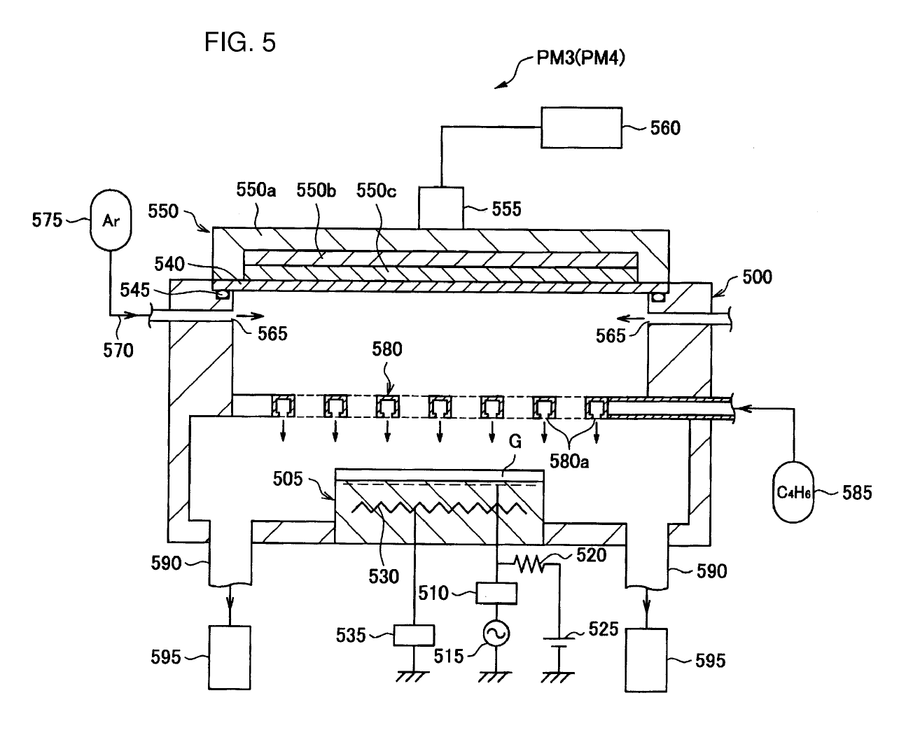

Next, the glass substrate G is transferred to the microwave plasma processing apparatus PM3, which corresponds to a first microwave plasma processing apparatus, under the control of the controller 20. As shown in the cross section f of FIG. 1, the microwave plasma processing apparatus PM3 forms the aCHx film 54 to cover the organic EL element with the close-contact layer 53 interposed between the aCHx film 54 and the organic EL element. FIG. 5 is a vertical cross-sectional view of the microwave plasma processing apparatus PM3 that performs film formation.

The microwave plasma processing apparatus PM3 includes a processing container 500 in the shape of a rectangular solid whose ceiling is open. The processing container 500 is formed of, for example, aluminum alloy, and is grounded. A loading table 505 to load the glass substrate G thereon is formed at the center of the bottom of the processing container 500. A high frequency power supply source 515 is connected to the loading table 505 via a matcher 510, and a predetermined bias voltage is applied into the loading table 505 by high frequency power output from the high frequency power supply source 515. A high voltage direct current (DC) power supply source 525 is connected to the loading table 505 via a coil 520, and electrostatically adsorbs the glass substrate G by using a DC voltage output from the high voltage DC power supply source 525. Also, a heater 530 is installed inside the loading table 505. The heater 530 is connected to an alternating current (AC) power supply source 535, and maintains the glass substrate G at a predetermined temperature by using an AC voltage output from the AC power supply source 535.

The opening in the ceiling portion of the processing container 500 is closed by a dielectric plate 540 formed of, for example, quartz, and the inner space of a processing chamber is air-tightly maintained by an O-ring 545 that is formed between the processing container 500 and the dielectric plate 540.

A radial line slot antenna (RLSA) 550 is installed on the upper surface of the dielectric plate 540. The RLSA 550 includes an antenna body 550a whose bottom is open, and thus in the open bottom of the antenna body 550a, a wavelength-shortening plate 550b formed of a low-loss dielectric material is installed, and a slot plate 550c having a plurality of slots formed therein is installed on the wavelength-shortening plate 550b.

The RLSA 550 is connected to a microwave generator 560 existing outside the microwave plasma processing apparatus PM3, via a coaxial waveguide 555. Microwaves of 2.45 GHz, for example, output from the microwave generator 560 are propagated into the antenna body 550a of the RLSA 550 via the coaxial waveguide 555, wavelength-shortened by the wavelength-shortening plate 550b, and then circularly polarized by the slots of the slot plate 550c and supplied into the processing container 500.

A plurality of gas inlets 565 for supplying gas are formed in upper lateral sidewalls of the processing container 500, and communicate with an argon gas supply source 575 via a gas line 570. A gas shower plate 580 having an approximately flat-plate shape is formed at or near the center of the processing chamber. The gas shower plate 580 is a lattice of gas pipes that intersect with one another. A plurality of gas holes 580a are formed in the gas pipes, respectively, so as to face the loading table 505. The gas holes 580a formed in the gas pipes are equally spaced from each other. A butyne (C₄H₆) gas supplied from a butyne gas supply source 585 communicating with the gas shower plate 580 is equally discharged from the gas holes 580a of the gas shower plate 580 toward the glass substrate G.

An exhaust apparatus 595 is attached to the processing container 500 via the gas exhaust pipe 590, and thus exhausts the gas from the processing container 500, so that the processing chamber is depressurized to a desired vacuum degree.

In the microwave plasma processing apparatus PM3 having the above-described structure, the controller 20 controls the internal pressure of the processing chamber to be 20 mTorr or less by the vacuum apparatus 595, microwave power supplied from the microwave generator 560 into the processing chamber to be 5 kw/cm² or more, and a temperature around the glass substrate G loaded on the processing chamber (for example, a surface temperature of the substrate) to be 100° C. or less. In this condition, according to a 1:1 flow rate ratio of the argon gas to the butyne gas, the argon gas (inert gas) is supplied at 50 sccm from the gas inlets 565 existing in the upper portion of the processing chamber, and the butyne gas is supplied at 50 sccm from the gas shower plate 580 existing in the middle portion of the processing chamber. Accordingly, the mixture gas is excited by the microwave power to produce plasma, and the aCHx (amorphous hydrocarbon) film 54 is formed at a low temperature less than or equal to 100° C. by using the plasma.

The aCHx film 54 is formed as a stress relaxing layer from among protection films used to protect the organic EL element. Accordingly, the aCHx film 54 may be somewhat thick. For example, the aCHx film 54 may have a thickness of 500 to 3000 Å. By having such a somewhat high thickness, the aCHx film 54 may relax the stress generated in the SiNx film 55 formed after the aCHx film 54, and also prevent nitrogen included in the SiNx film from reaching the organic EL element. In more detail, oxygen molecules or water molecules may be diffused by a distance determined by a diffusion coefficient. Accordingly, if a period of time required for the oxygen molecules or the water molecules to reach the organic EL element is longer than a period of time required for the oxygen molecules or the water molecules to be destroyed while being diffused, those molecules do not affect the organic EL element in a bad way. Thus, the organic EL element is marketable. Therefore, in relation to the diffusion coefficient, if the aCHx film 54 has a thickness of 500 to 3000 Å, even when the oxygen molecules or the water molecules passed through the SiN film and entered the organic EL element, the probability that the oxygen molecules or the water molecules affect the organic EL element in a bad way is very low.

The close-contact layer 53 may be formed by being pre-cleaned and continuously processed in the process module PM3, instead of being formed in the process module PM6 of FIG. 2. In this case, the process module PM3 consecutively performs pre-cleaning, formation of the close-contact layer 53, and formation of the aCHx film 54. In this case, in the formation of the close-contact layer 53, the silane coupling agent of HMDS, and a rare gas, an H₂ gas, or an N₂ gas is supplied from the gas holes 580a of the gas shower plate 580 without establishing plasma and is thus adsorbed to the organic EL element. Thereafter, the argon gas is plasma-ignited before the aCHx film 54 undergoes microwave plasma CVD, so that a combination of Si and NH in HMDS is disconnected by argon (ions) included in plasma. Alternatively, after HMDS as the silane coupling agent and the H₂ gas are adsorbed to the organic EL element, the combination of Si and NH in HMDS may be disconnected by ions included in plasma generated during microwave plasma CVD process on the aCHx film 54. The separated NH is exhausted during the microwave plasma process.

(PM4: Formation of the SiNx Film 55)

Thereafter, the glass substrate G is transferred to the process module PM4 (hereinafter, referred to as a microwave plasma processing apparatus PM4), which corresponds to a second microwave plasma processing apparatus, under the control of the controller 20. The microwave plasma processing apparatus PM4 forms the SiNx film 55 on the aCHx film 54. The internal structure of the microwave plasma processing apparatus PM4 is the same as that of the microwave plasma processing apparatus PM3 shown in FIG. 5, so a detailed description thereof will be omitted.

In the microwave plasma processing apparatus PM4 having the above-described structure, the controller 20 controls the internal pressure of the processing chamber to be 10 mTorr or less by the vacuum apparatus 595, microwave power supplied from the microwave generator 560 into the processing chamber to be 5 kw/cm² or more, and a temperature around the glass substrate G loaded on the processing chamber (for example, a surface temperature of the substrate) to be 100° C. or less. In this condition, the argon gas is supplied at 5 to 500 sccm from the upper portion of the processing chamber and a silane (SiH₄) gas is supplied at 0.1 to 100 sccm from the gas shower plate 580, whereas the silane gas and a nitrogen gas are supplied at a flow rate ratio of 1:100. Accordingly, the mixture gas is excited by the microwave power to produce plasma, and the SiNx (silicon nitride) film 55 is formed at a low temperature by using the plasma. Considering an influence on the organic EL element, it is more preferable that the surface temperature of the glass substrate G is controlled to be 70° C. or less.

The SiNx film 55 is formed as a sealing layer from among the protection films used to protect the organic EL element. In order to maintain a balance between moisture repellency or oxidization resistance of the protection films and a stress included in the organic EL element, the SiNx film 55 needs to be somewhat thin. For example, it is m preferable that the SiNx film 55 has a thickness of 1000 Å or less.

If a layer closely contacted to the organic EL element from among the protection films is formed of a film including nitrogen, for example a CNx film, the organic EL element which is an underlayer may be nitrified, and thus there is a risk of changing the organic EL element. For example, if a nitride film exists on an aluminum (Al) electrode of the organic EL element, the Al electrode is nitrified to turn into AIN, and the AIN serves as an insulation material or a dielectric material. Thus, it is difficult for electricity to flow and consequently, luminous intensity decreases. In addition, when nitride is directly mixed with an active layer of the organic EL element, the nitride directly damages the organic EL element, and thus the characteristics of the organic EL element are changed.

However, as described above, the protection film according to the present embodiment has a hierarchical structure including a stress relaxing layer (the aCHx film 54) including a carbon component and not including a nitrogen component, and a sealing layer (the SiNx film 55) including a nitrogen component. Accordingly, moisture repellency or oxidization resistance of the organic EL element is strongly maintained by the sealing layer, and also the stress of the sealing layer is relaxed by the stress relaxing layer in order to prevent stresses from being applied to the organic EL element. In addition, since the stress relaxing layer closely contacted to the organic EL element does not include nitrogen, the characteristics of the organic EL element may be maintained good.

As described above, in the method of manufacturing an organic electronic device according to the present embodiment, a protection film that is well-balanced by satisfying all demands \textcircled{1} to sufficiently protect the organic EL element from a physical impact, \textcircled{2} to be formed at low temperature, \textcircled{3} to be moisture-repellent and oxidization-resistant, and \textcircled{4} to provide a low stress may be formed. Consequently, the protection film according to the present embodiment protects the organic EL element from water or oxygen and prevents the organic EL element from being nitrified, thereby reducing the stress to be applied to the organic EL element by relaxing the stress of the protection film by itself without degrading the luminous intensity, durability, or the like. Therefore, detachment or damage of the device, particularly, an interface between layers of the device, may be effectively prevented.

In addition, in the present embodiment, since an aCHx film and a SiNx film are formed particularly using an RLSA type microwave plasma processing apparatus, an electron temperature is low, compared with a case where the aCHx film and the SiNx film are formed using a parallel plate plasma processing apparatus. Thus, dissociation of gas may be easily controlled, and thus a high quality film may be formed.

If, after pre-cleaning, the aCHx film 54 is stacked without forming the close-contact layer 53, the aCHx film 54 may be consecutively formed in a microwave plasma processing apparatus where pre-cleaning was performed. Accordingly, process efficiency may be increased.

Also, the aCHx film 54 and the SiNx film 55 may be hierarchically formed. Thus, a stress in the protection film including the aCHx film 54 and the SiNx film 55 may be effectively dispersed within the protection film.

Moreover, a hydrocarbon gas having a multiple bond instead of the butyne gas may be used as a gas which is supplied during formation of the aCHx film. Examples of the hydrocarbon gas having a multiple bond include an ethylene (C₂H₄) gas that has a double bond, an acetylene (C₂H₂) gas that has a triple bond, a pentyne (C₅H₁₀) gas such as 1-pentyne, 2-pentyne, or the like, and a mixture gas of one of these gases having multiple bonds with a hydrogen gas. Among the butyne gas, it is more preferable to use a 2-butyne gas. A Si₂H₆ gas instead of a SiH₄ gas may be used as a gas that is supplied during formation of the SiNx film. In addition to the SiH₄ gas or the Si₂H₆ gas, Monomethylsilane (CH₃SiH₃), Dimethylsilane ((CH₃)₂SiH₂), or Trimethylsilane ((CH₃)₃SiH) may be used.

### Embodiment II

Embodiment II of the present invention will now be described in detail. The present embodiment is different from Embodiment I, whose SiNx film 55 does not have hierarchical structure, in terms of structure in that the SiNx film 55 has a hierarchical structure. Thus, the embodiment II will now be described by focusing on a structure of the SiNx film 55 that is different from Embodiment I.

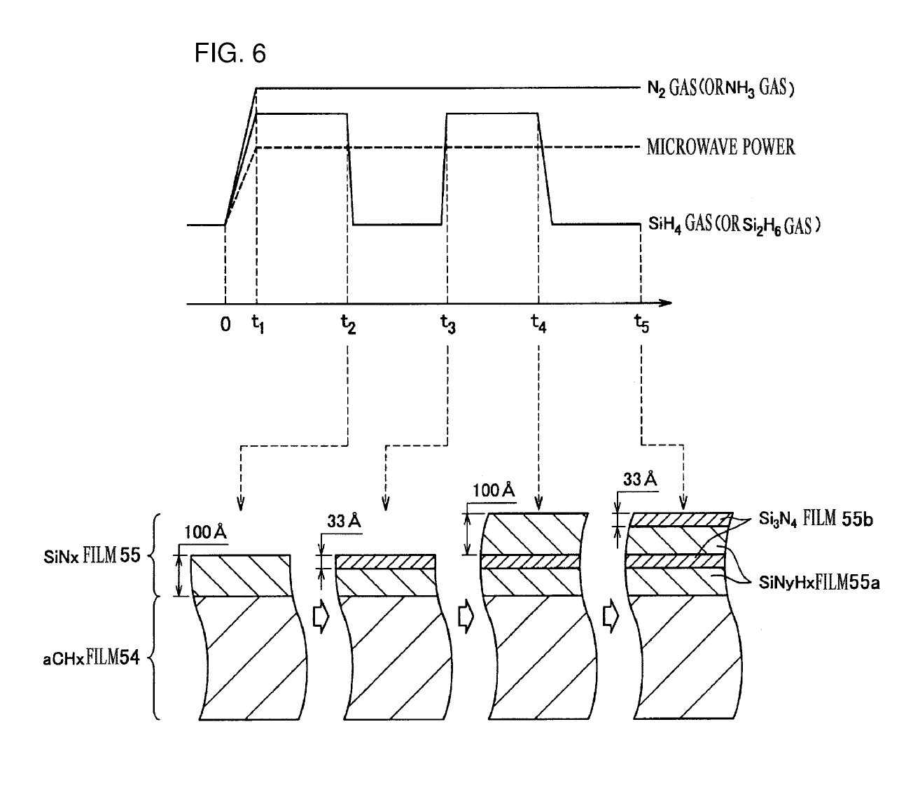

In the present embodiment, when the microwave plasma processing apparatus PM4 forms a SiNx film, a silane (SiH₄) gas (or a Si₂H₆ gas) is discontinuously supplied as shown in the time chart in the upper part of FIG. 6, under the control of the controller 20. In other words, at a time t₁ after a predetermined period of time lapses from supply of the silane gas and a nitrogen gas and introduction of microwave power, the gas supply and the microwave power supply are stabilized, and at a time t₂ after a predetermined period of time lapses from the time t₁, the SiNyHx film 55a having a thickness of about 100 Å is stacked on the aCHx film 54 as shown in the lower part of FIG. 6. When the stacking of the SiNyHx film 55a to the thickness of about 100 Å is completed, only the supply of the silane gas is paused, and the nitrogen gas and the microwave power are continuously supplied, as shown in the upper part of FIG. 6.

When the supply of the silane gas is paused, the amount of the nitrogen gas is relatively increased, and thus reformation occurs on the SiNyHx film 55a starting from a surface layer thereof due to the nitrogen gas. Thus, at a time t₃ after a predetermined period of time lapses, about one third of the SiNyHx film 55a is nitrified to turn into a nitrified silicon nitride film like, for example, the Si₃N₄ film 55b, as shown in the lower part of FIG. 6: The supply of the silane gas is paused until the nitrified silicon nitride film such as the Si₃N₄ film 55b is formed due to nitrification of about ⅓ to ½ of the SiNyHx film 55a as described above. Thereafter, as shown in the upper part of FIG. 6, the supply of the silane gas resumes at the time t₃. The nitrogen gas and the microwave power are also continuously supplied.

When the supply of the silane gas resumes, the amount of the nitrogen gas is relatively decreased. In this state, at a time t₄ after a predetermined period of time lapses, the SiNyHx film 55a having a thickness of about 100 Å is again stacked on the Si₃N₄ film 55b as shown in the lower part of FIG. 6. When the Si₃N₄ film 55b is stacked to the thickness of about 100 Å, the supply of the silane gas is again paused, and only to the nitrogen gas and the microwave power are supplied, as shown in the upper part of FIG. 6. At a time t₅ after a predetermined period of time lapses, about one third of the SiNyHx film 55a, which is the secondly stacked SiNyHx film 55a, is nitrified to form the Si₃N₄ film 55b again as shown in the lower part of FIG. 6.

As described above, in the present embodiment, after the SiNyHx film 55a, which corresponds to a first silicon nitride film, is formed, the supply of the silane gas is paused, and the SiNyHx film 55a is nitrified by the nitrogen gas, so that the Si₃N₄ film 55b, which corresponds to a second silicon nitride film and is denser than the SiNyHx film 55a, is formed. By repeating the pause of the supply of the silane gas and resumption of the supply of the silane gas, the SiNyHx film 55a and the Si₃N₄ film 55b are consecutively stacked within the same microwave plasma processing apparatus. Thus, a silicon nitride film having a hierarchical structure is formed.

When the silicon nitride film is nitrified, it turns into a denser film, and thus has improved sealing performance. Considering oxygen resistance, moisture repellency, a mechanical strength, a pin hole, and other flaws, the silicon nitride film needs to be somewhat thick. However, since the stress of the silicon nitride film increases proportionally as the silicon nitride film becomes denser due to nitrification, the silicon nitride film cannot be so thick as a single-layered film. Considering this property of the film, in the present embodiment, the SiNyHx film 55a, and the Si₃N₄ film 55b reformed to be denser than the SiNyHx film 55a due to nitrification are alternately stacked. Consequently, the stress of the entire silicon nitride film may be relaxed, and also the silicon nitride film may be formed to be somewhat thick, so that the sealing performance of the entire silicon nitride film may be reinforced.

Also, in the manufacturing method according to the present embodiment, the SiNyHx film 55a and the Si₃N₄ film 55b are consecutively and alternately stacked within the same microwave plasma processing apparatus, so that efficient processing may be obtained.

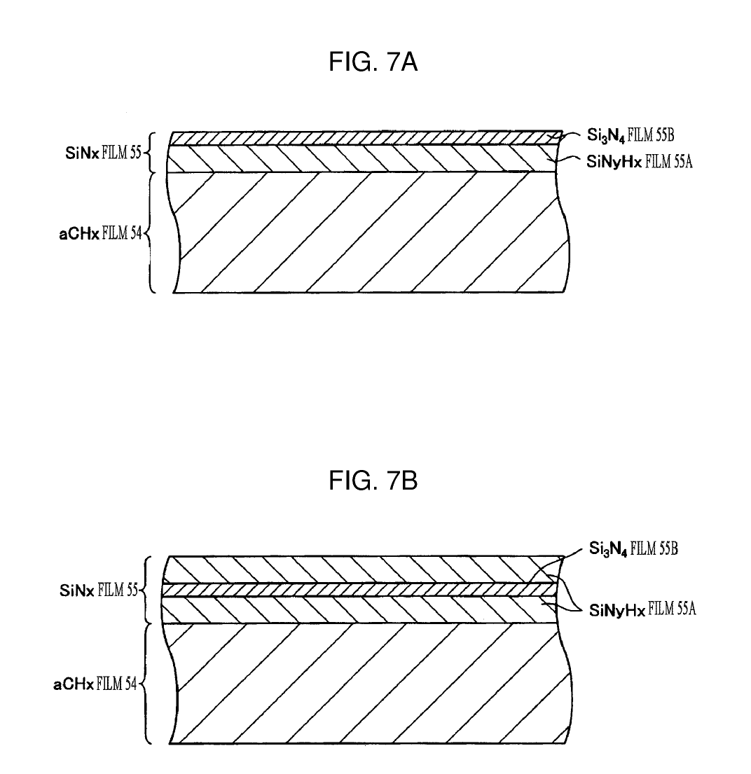

To form the layered structure of the silicon nitride film, the SiNyHx film 55a and the Si₃N₄ film 55b may be stacked to form a single layer each as shown in FIG. 7A, or a single Si₃N₄ film 55b may be interposed between two SiNyHx films 55a as shown in FIG. 7B. Alternatively, the SiNyHx film 55a and the Si₃N₄ film 55b may be alternately stacked a plurality of times. In this case, as the number of times of stacking operations increases, it is difficult for the stress of the silicon nitride film to increase although a sum of the thicknesses of the stacked films is high. However, considering the mechanical strength of the organic electronic device or the load of processing, a single layer (FIG. 7A), one and a half layer (FIG. 7B), or two layers (FIG. 6) etc. are suitable.

To maintain a balance between the oxygen resistance or moisture repellency of the protection film and a stress existing in the protection film, the SiN film needs to be somewhat thin. For example, a sum of the thicknesses of the first SiN film, for example, the SiNyHx film (55a), and the second SiN film, for example, the Si₃N₄ film 55b, may be less than or equal to 1000 Å.

During this consecutive processing, the controller 20 may control a film thickness ratio of the Si₃N₄ film 55b to the SiNyHx film 55a by controlling the timings of the pause of the supply of the silane gas and resumption of the supply of the silane gas. As described above, since the Si₃N₄ film 55b has high sealing performance but has high film stress, if the thickness of the Si₃N₄ film 55b is equal to or greater than a predetermined thickness, the probability that the silicon nitride film is cracked or detached increases. Therefore, it is preferable that the film thickness ratio of the Si₃N₄ film 55b to the SiNyHx film 55a is ½ to ⅓, and thus the cracking or detachment of the silicon nitride film may be prevented.

Even when the stress existing in the silicon nitride film is effectively distributed within the silicon nitride film by hierarchically forming the silicon nitride film as described above, the amorphous hydrocarbon (aCHx) film needs to be interposed between the silicon nitride film and the organic EL element in order to prevent the stress of the silicon nitride film from being applied to the organic EL element. This necessity appears in Embodiment II as in Embodiment I.

In each of Embodiments I and II, an organic electronic device covered with a protection film that has high sealing performance while relaxing a stress and does not change the characteristics of an organic EL element may be manufactured.

(Application of Bias Voltage)

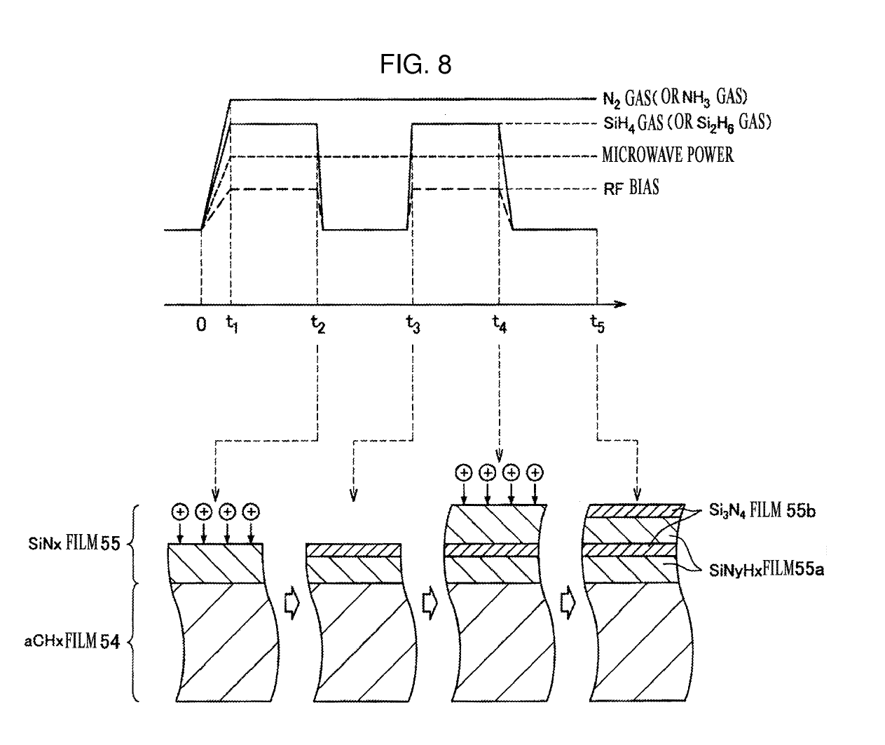

When the protection film is formed, a predetermined bias voltage may be applied to the loading table 505 by the high frequency power output from the high frequency power supply source 515 at a predetermined timing. For example, in a time chart shown in the upper part of FIG. 8, a bias voltage is applied during a period of time t₁ to t₂ and a period of time t₃ to t₄. The high frequency power output from the high frequency power supply source 515 may have a frequency of 1 MHz to 4 MHz and power of 0.01 to 0.1 W/cm². In this case, for example, a bias voltage with power of 0.05 W/cm² may be applied.

As described above, when the bias voltage is applied at the same time when the SiNyHx film 55a is stacked, ions included in plasma are introduced, and thus the film may be reconstructed during film formation by the energy of the ions, as shown in the lower part of FIG. 8. Accordingly, the stress of the SiNyHx film 55a is relaxed, and thus stress and damage on the underlayer of the SiNyHx film 55a may be reduced.

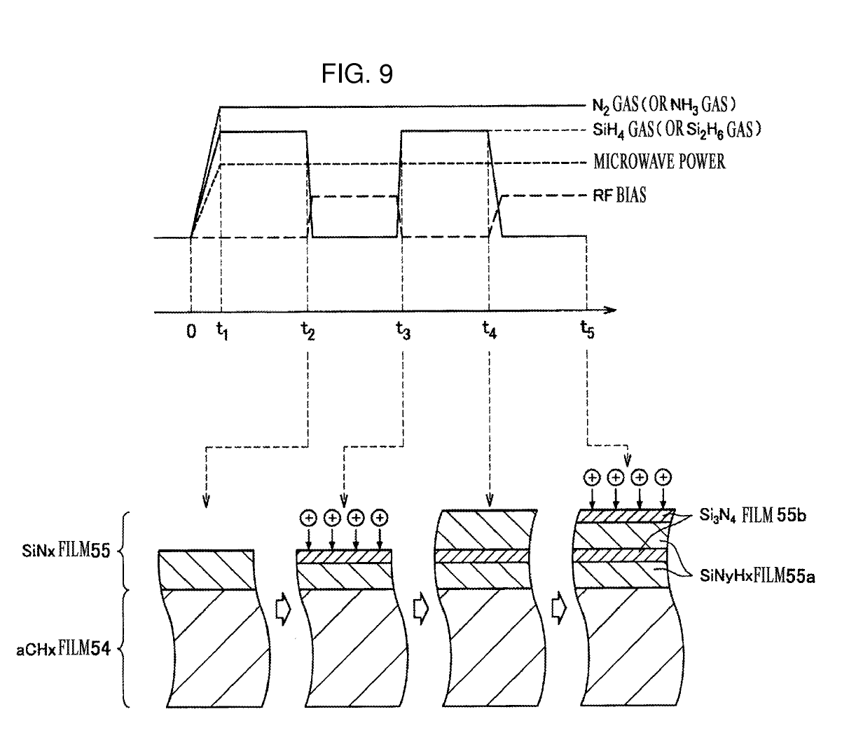

For example, in the time chart shown in the upper part of FIG. 9, a bias voltage is applied during a period of time t₂ to t₃ and a period of time t₄ to t₅. As described above, if the bias voltage is applied at the same time when the SiNyHx film 55a is reformed into the Si₃N₄ film 55b, N ions may be introduced directly into the film as shown in the lower part of FIG. 9. Accordingly, the Si₃N₄ film 55b, which is denser than the SiNyHx film 55a, is formed, thereby improving the sealing performance of the film.

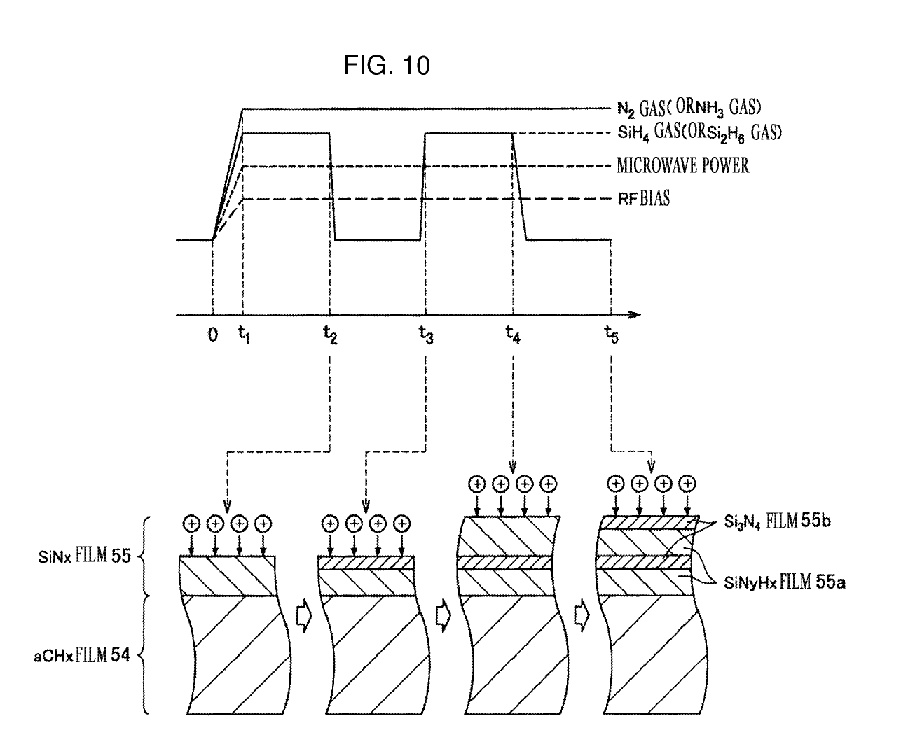

For example, in the time chart shown in the upper part of FIG. 10, a bias voltage is applied during a period of time t₁ to t₅. According to this, as shown in the lower part of FIG. 10, reconstruction of the SiNyHx film 55a and reformation into the Si₃N₄ film 55b may be overall achieved. Consequently, the stress of the entire protection film may be relaxed, and also the sealing performance thereof may be reinforced.

The NH₃ gas instead of the N₂ gas may be supplied. Also, the Si₂H₆ gas instead of the SiH₄ gas may be supplied.

The size of the glass substrate G may be equal to or greater than 730 mm×920 mm. For example, the size of the glass substrate G may be equal to or greater than a G4.5 substrate size of 730 mm×920 mm (diameter of the inner space of a chamber: 1000 mm×1190 mm) or equal to or greater than a G5 substrate size of 1100 mm×1300 mm (diameter of the inner space of a chamber: 1470 mm×1590 mm). A target object on which an element is formed is not limited to a glass substrate G having one of the aforementioned sizes, and may be a 200 mm or 300 mm silicon wafer.

In Embodiments I and II, operations of each components are related with one another, and considering the relation between the units, they may be replaced by a series of operations. Due to this replacement, an embodiment of a method of manufacturing an organic electronic device may be an embodiment of an apparatus for manufacturing the organic electronic device.

While the present invention has been particularly shown and described with reference to exemplary embodiments thereof, the present invention is not limited thereto. It will be understood by those of ordinary skill in the art that various changes in form and details may be made therein without departing from the spirit and scope of the present invention as defined by the following claims. It will be understood that those changes are also within the technical range of the present invention.

For example, a protection film according to the present invention is not limited to a sealing film for an organic EL element but may be used as a sealing film for an organic metal element formed by metal organic chemical vapor deposition (MOCVD) in which a thin film is grown on a target object by mainly using organic metal liquid as a film-formation material and dissolving a vaporized film-formation material on the target object heated to 500 to 700° C. The protection film according to the present invention may also be used to seal an organic element such as an organic transistor, an organic Field Effect Transistor (FET), or an organic solar battery, or an organic electronic device such as a thin film transistor (TFT) used in a system for driving liquid crystal display.

In addition, an apparatus for manufacturing the protection film according to the present invention may be the above-described RLSA type microwave plasma processing apparatus having a planar antenna with a plurality of slots, but may not be limited thereto. For example, the apparatus for manufacturing the protection film according to the present invention may be Cellular Micro-wave Excitation Plasma (CMEP) apparatuses which has a plurality of dielectric plates formed on a ceiling side of a processing container in a tile configuration and plasma-processes a target object by plasmatizing a gas within a processing chamber by the power of microwaves which transmitted through each of the dielectric plates via slots formed in each of the dielectric plates.

1. An organic electronic device comprising:
an organic element formed on a target object; and
a protection film that covers the organic element,
wherein the protection film comprises:
a stress relaxing layer that is formed to be adjacent to the organic element and cover the organic element, and contains a carbon component and contains no nitrogen components; and
a sealing layer that is formed on the stress relaxing layer and contains a nitrogen component.

2. The organic electronic device of claim 1, wherein a close-contact layer formed of a coupling agent is interposed between the organic element and an exposed portion of the target object, and the stress relaxing layer.

3. The organic electronic device of claim 1, wherein the stress relaxing layer is formed of an amorphous hydrocarbon film.

4. The organic electronic device of claim 1, wherein the sealing layer is formed of a silicon nitride film.

5. The organic electronic device of claim 4, wherein the silicon nitride film comprises a first silicon nitride film and a second silicon nitride film obtained by further nitrifying the first silicon nitride film.

6. The organic electronic device of claim 5, wherein the second silicon nitride film is interposed between first silicon nitride films.

7. The organic electronic device of claim 5, wherein the first silicon nitride film and the second silicon nitride film are alternately stacked to have one layer each or two layers each.

8. The organic electronic device of claim 5, wherein a film thickness ratio of the second silicon nitride film to the first silicon nitride film is ½ to ⅓.

9. The organic electronic device of claim 3, wherein a thickness of the amorphous hydrocarbon film is 500 to 3000 Å.

10. The organic electronic device of claim 8, wherein a sum of a thickness of the first silicon nitride film and a thickness of the second silicon nitride film is less than or equal to 1000 Å.

11. The organic electronic device of claim 1, wherein the organic element is an organic electroluminescence (EL) element in which a plurality of organic layers are consecutively formed.

12. A method of manufacturing an organic electronic device, the method comprising:
forming an organic element on a target object; and
stacking a stress relaxing layer to be adjacent to the organic element and cover the organic element, to serve as one layer included in a protection film that protects the organic element, wherein the stress relaxing layer contains a carbon component and contains no nitrogen components; and
stacking a sealing layer on the stress relaxing layer, to serve as another layer included in the protection film, wherein the sealing layer contains a nitrogen component.

13. The method of claim 12, wherein a close-contact layer formed of a coupling agent is formed on the organic element and an exposed portion of the target object, and to then the stress relaxing layer is stacked thereon.

14. The method of claim 12, wherein a film stacked as the stress relaxing layer is an amorphous hydrocarbon film formed using plasma generated by exciting a gas comprising a butyne gas by microwave power.

15. The method of claim 14, wherein the amorphous hydrocarbon film is formed in a process condition where an internal pressure of a processing chamber of a first microwave plasma processing apparatus is 20 mTorr or less, microwave power supplied into the processing chamber is 5 kw/cm² or greater, and a temperature around the target object loaded within the processing chamber is 100° C. or less.

16. The method of claim 12, wherein a film stacked as the sealing layer comprises a first silicon nitride film formed using plasma generated by exciting a gas comprising a silane gas and a nitrogen gas by microwave power.

17. The method of claim 16, wherein the first silicon nitride film is formed in a process condition where an internal pressure of a processing chamber of a second microwave plasma processing apparatus is 10 mTorr or less, microwave power supplied into the processing chamber is 5 kw/cm² or greater, and a temperature around the target object loaded within the processing chamber is 100° C. or less.

18. The method of claim 17, wherein during the formation of the first silicon nitride film, the temperature around the target object is set to be 70° C. or less.

19. The method of claim 16, wherein the film stacked as the sealing layer comprises a second silicon nitride film that is formed by nitrifying the vicinity of a surface layer of the first silicon nitride film by the nitrogen gas when supply of the silane gas is paused, after forming the first silicon nitride film.

20. The method of claim 19, wherein the formation of the first silicon nitride film and the formation of the second silicon nitride film by reformation of the first silicon nitride film are consecutively performed by repeating the pause of the supply of the silane gas and resumption of the supply of the silane gas.

21. The method of claim 20, wherein a film thickness ratio of the second silicon nitride film to the first silicon nitride film is controlled to be ½ to ⅓ by controlling the timings of the pause of the supply of the silane gas and the resumption of the supply of the silane gas.

22. The method of claim 13, wherein, before the close-contact layer is formed, the organic element and the exposed portion of the target object are cleaned using plasma generated by exciting an inert gas by microwave power.

23. The method of claim 22, wherein the cleaning is performed in a process condition where an internal pressure of a processing chamber of a microwave plasma processing apparatus is 100 to 800 mTorr or less, microwave power supplied into the processing chamber is 4 to 6 kw/cm² or greater, and a temperature around the target object is 100° C. or less.

24. The method of claim 19, wherein the amorphous hydrocarbon film and the first and second silicon nitride films are formed using a plasma processing apparatus comprising a radial line slot antenna (RLSA).

25. The method of claim 22, wherein the amorphous hydrocarbon film is formed consecutively in the processing chamber of the microwave plasma processing apparatus where the cleaning has been performed.

26. The method of claim 12, wherein a bias voltage is applied during at least one selected from the group consisting of a period of time when the stress relaxing layer is stacked and a period of time when the sealing layer is stacked.

27. An apparatus for manufacturing an organic electronic device, wherein the apparatus:
forms an organic element on a target object;
stacks a stress relaxing layer to be adjacent to the organic element and cover the organic element, to serve as one layer included in a protection film that covers the organic element, wherein the stress relaxing layer contains a carbon component and contains no nitrogen components; and
stacks a sealing layer on the stress relaxing layer, to serve as another layer included in the protection film, wherein the sealing layer contains a nitrogen component.

28. A substrate processing system in which a substrate processing apparatus comprising a deposition apparatus, a first microwave plasma processing apparatus, and a second microwave plasma processing apparatus is arranged in a cluster structure, and an organic electronic device is manufactured while maintaining a space where a target object moves from an area where the target object is carried in to an area where the target object is carried out in a desired depressurized state,
wherein the substrate processing system:
forms an organic element within a processing chamber of the deposition apparatus;
generates plasma by exciting a gas including a butyne gas by microwave power and forms an amorphous hydrocarbon film to be adjacent to the organic element and cover the organic element by using the plasma, within a processing chamber of the first microwave plasma processing apparatus; and
generates plasma by exciting a gas including a silane gas and a nitrogen gas by microwave power and forms a first silicon nitride film on the amorphous hydrocarbon film by using the plasma, within a processing chamber of the second microwave plasma processing apparatus.

29. The substrate processing system of claim 28, wherein the first microwave plasma processing apparatus and the second microwave plasma processing apparatus are plasma processing apparatuses each including an RLSA.

30. The substrate processing system of claim 28, wherein, after the organic element and an exposed portion of the target object are cleaned in the processing chamber of the first microwave plasma processing apparatus, the amorphous hydrocarbon film is consecutively formed within the same processing chamber.

31. The substrate processing system of claim 28, wherein:
the substrate processing system comprises a processing chamber in which a close-contact layer formed of a coupling agent is formed on the organic element and the exposed portion of the target object; and
after the organic element and the exposed portion of the target object are cleaned, the close-contact layer is formed in the processing chamber, and the amorphous hydrocarbon film is stacked in the first microwave plasma processing apparatus.

32. The substrate processing system of claim 28, wherein the organic element is an organic EL element in which a plurality of organic layers are consecutively formed in the processing chamber of the deposition apparatus.

33. A protection film structure for protecting an organic element formed on a target object, the protection film structure comprising:
a stress relaxing layer stacked adjacent to the organic element to cover the organic element, to serve as one layer included in the protection film, wherein the stress relaxing layer contains a carbon component and contains no nitrogen components; and
a sealing layer stacked on the stress relaxing layer, to serve as another layer included in the protection film, wherein the sealing layer contains a nitrogen component.

34. The protection film structure of claim 33, wherein a close-contact layer formed of a coupling agent is interposed between the organic element and an exposed portion of the target object, and the stress relaxing layer.

35. A computer-readable recording medium having recorded thereon a control program that operates on a computer, wherein the computer controls a substrate processing system to manufacture an organic electronic device according to the method of claim 12.
